(19) United States
(12) Patent Application Publication
(10) Pub. No.: US 2008/0017964 A1
(43) Pub. Date: Jan. 24, 2008

(54) Hybrid Microelectronic Package

(76) Inventors: Donald E. Schott, Colorado Springs, CO (US); Peter J. Martinez, Colorado Springs, CO (US)

Correspondence Address: AGILENT TECHNOLOGIES INC., INTELLECTUAL PROPERTY ADMINISTRATION,LEGAL DEPT., MS BLDG. E P.O. BOX 7599, LOVELAND, CO, 80537, US

(21) Appl. No.: 11/458,808

(22) Filed: Jul. 20, 2006

(51) Int. Cl. H01L 23/02

(52) U.S. Cl. 257/680

(57) ABSTRACT

A method and apparatus with a first substrate made of an inorganic material having at least one signal trace and a second substrate made of an organic material having at least one signal trace, at least one interconnect and at least one reception cavity. The first and second substrates are mechanically joined and the at least one signal trace of the first substrate is electrically connected to the at least one signal trace of the second substrate. The first substrate overlays the reception cavity.

### BACKGROUND

The two broad categories of materials conventionally used as microelectronic package substrates are glasses or ceramics and plastic, epoxy, or composites of glass and plastic or epoxy. Each type of material has advantages and disadvantages for different types of package applications. Specifically, the glass or ceramic substrates have superior thermal and electrical properties, particularly in the high frequency realm, but are more costly to produce than the plastic or composite substrates. The plastic or composite substrates generally have a more reliable interconnection to a host printed circuit board (herein “PCB”) because there is less of a difference in the magnitude of the coefficient of thermal expansion for the substrate and host PCB, but the plastic or composite substrates do not have the intrinsic electrical properties of the dielectric nor the trace metallization fidelity of ceramic and glass. In prior art ceramic IC substrates, the reliability of the interconnection degrades as the size of the interconnections between the package and the host PCB increases.

Prior art hybrid microelectronic packages have a metal base plate with an IC disposed thereon and a plastic substrate. Electrical connection is made between the IC and a conductive element on the substrate. The metal base plate provides for improved thermal dissipation properties, but does not provide features for improved high frequency performance.

There is a need for an improved high frequency microelectronic package with improved interconnection reliability and lower cost.

### BRIEF DESCRIPTION OF THE DRAWINGS

An understanding of the present teachings can be gained from the following detailed description, taken in conjunction with the accompanying drawings of which like reference numerals in different drawings refer to the same or similar elements.

FIG. 1 is a top plan view of an embodiment of a microelectronic package according to the present teachings.

FIG. 2 is a bottom plan view of the package shown in FIG. 1.

FIG. 3 is a side elevation view of the package shown in FIG. 1.

FIG. 4 is a cross sectional view of an embodiment of a package according to the present teachings.

FIG. 5 is a cross sectional view of a portion of another embodiment of a package according to the present teachings.

FIG. 6 is a cross sectional view of a portion of yet another embodiment of a package according to the present teachings.

FIG. 7 is a perspective view of a cross sectional portion of another embodiment according to the present teachings.

FIG. 8 a plan view of a portion of another embodiment according to the present teachings.

FIG. 9 is a flow chart of a method for making a package according to the present teachings.

### DETAILED DESCRIPTION

In the following detailed description, for purposes of explanation and not limitation, example embodiments disclosing specific details are set forth in order to provide an understanding of embodiments according to the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatus and methods may be omitted so as to not obscure the description of the example embodiments. Such methods and apparatus are clearly within the scope of the present teachings.

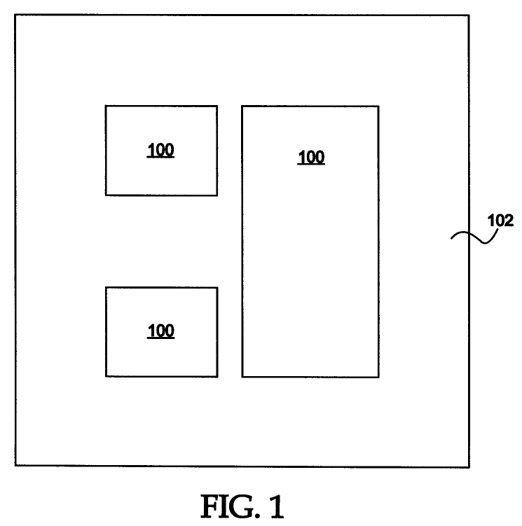

With specific reference to FIG. 1 of the drawings that illustrates a top plan view of a package according to the present teachings, a hybrid material microelectronic package has one or more first substrates 100 made of an inorganic material. The inorganic material is typically ceramic, glass or a ceramic and glass composite and has appropriate thermal dissipation properties for high power semiconductors and appropriate electrical properties for high frequency semiconductor applications. A second substrate 102 has at least one reception cavity 105 over which the first substrate 100 is disposed. For purposes of clarity of description in the present disclosure, reference is made to a single reception cavity 105 even though one of ordinary skill in the art appreciates that the teachings apply to multiple reception cavities 105. The second substrate 102 is made of an organic material such as plastic, epoxy, or a plastic epoxy composite such as FR4. Organic materials are typically lower cost and have thermal expansion properties more closely matched to most PCB materials onto which a microelectronic package may be mounted.

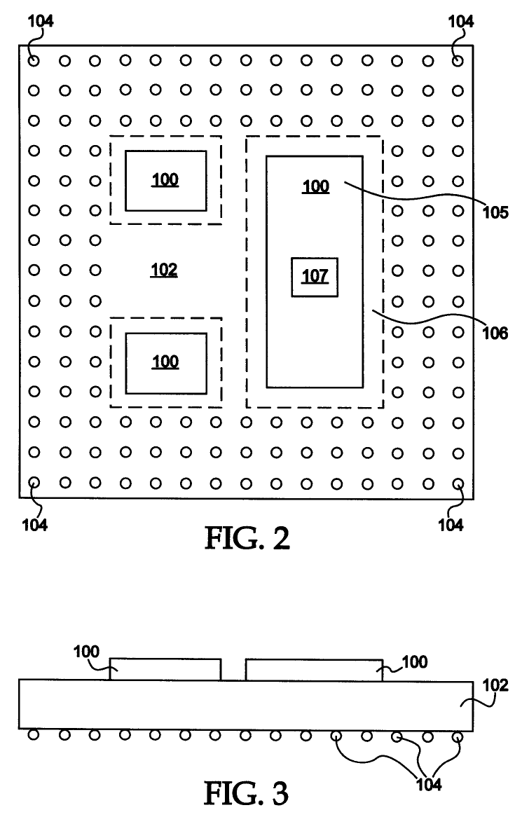

With specific reference to FIG. 2 of the drawings, that illustrates a bottom plan view of a package according to the present teachings, the second substrate 102 has at least one interconnect 104 and at least one reception cavity 105. The interconnect 104 is shown in the drawings as a ball in a plurality of interconnects making a ball grid array as is known in the art. Other interconnects such as pins, solder columns or land pads for connection to a pin socket are also appropriate depending upon the specific package requirements. The first substrate 100 is disposed over and is slightly larger than the reception cavity 105. Perimeter dimensions of the first substrate 100 are larger than perimeter dimensions of the reception cavity in the second substrate 102. The difference between the perimeter dimensions of the first substrate 100 and the perimeter dimensions of the reception cavity 105 in the second substrate 102 create a perimeter ledge 106 against which the first substrate 100 rests. The reception cavity 105 in the second substrate 102 exposes a portion of the first substrate 100. An integrated circuit 107 (herein “IC 107”) is disposed on and adhered to the first substrate 100 and is positioned on the first substrate 100 such that the IC 107 is within the reception cavity 105. Supporting electrical components and additional ICs 107 may also be disposed on the first substrate 100.

With specific reference to FIG. 3 of the drawings that illustrates a side view of the package shown in FIGS. 1 and 2 of the drawings, the first substrate 100 is disposed on a side of the second substrate 102 that is opposite the interconnects 104.

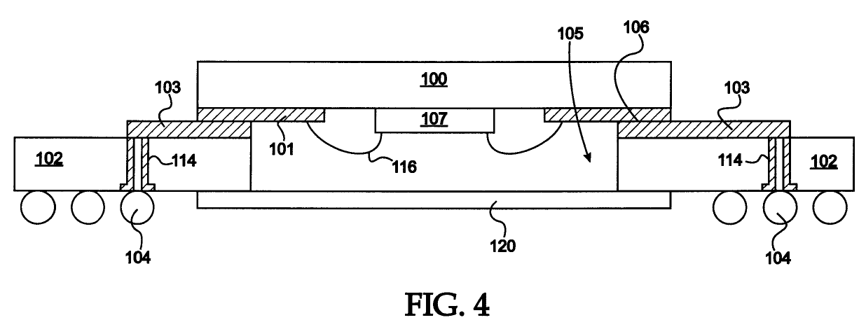

With specific reference to FIG. 4 of the drawings that illustrates a cross sectional view of an embodiment of a package according to the present teachings in which the first substrate 100 has only a single layer of metallization. In the embodiment of FIG. 4, the IC 107 is adhered to the first substrate 100 and is disposed within the reception cavity 105 of the second substrate 102. The first substrate 100 further has a metalized layer with at least one conductive element. In a specific embodiment, the conductive element may be a signal trace 101 and connections for power and reference potential or may be a ground plane or both. Connections from the IC 107 to signal, power and ground are made using a bond wire 116 or other conventional means. Although not shown in FIG. 4, the first substrate 100 may also have supporting passive components such as resistors and capacitors as well as additional ICs.

With further reference to FIG. 4 of the drawings, the signal traces 101 of the first substrate 100 are disposed so they align with mating signal traces 103 on the perimeter ledge 106 of the second substrate 102 when the first substrate 100 is properly positioned over the reception cavity 105. The mating signal traces 101 and 103 are selectively and electrically connected to each other using conventional means, such as solder or conductive epoxy. The electrical connection may also offer a mechanical connection of the first substrate 100 to the second substrate 102. Advantageously, this structure of mating signal traces 101, 103 minimizes discontinuities in the signal traces permitting high frequency bandwidth operation. The second substrate 102 may further include one or more signal vias 114 to carry the signal from the signal trace 103 to the interconnect 104 and host PCB. A lid 120 is disposed over the reception cavity 105 or cavities and rests on the second substrate 102. The lid 120 may be a thin flat sheet made of metal or other material suitable for the specific application thereby providing an air layer between the components 107 and conductive elements 116. Advantageously, a metal lid 120 provides enhanced electrical shielding for the package and its contents. In another embodiment, it may be acceptable to use a “glob top” to cover and provide dielectric protection for the components 107 and conductive elements 116. The “glob top” may be made of a non-conductive epoxy material as is conventional in the industry.

As one of ordinary skill in the art appreciates, the inorganic and organic materials have different coefficients of thermal expansion and thermal conductivity. During powered operation, the IC 107 heats and transfers the heat to the first substrate 100 upon which it is disposed. Advantageously, the inorganic material is able to effectively dissipate heat or conduct it to a heat sinking element external to the package. As is known, the first substrate 100 made of the inorganic material has a materially different thermal coefficient of expansion (herein “TCE”) from the organic material of the second substrate 102. The difference in TCE causes the first and second substrates 100, 102 to expand at different rates in response to the thermal increase. The different rates of expansion places stress on the mechanical connection between the two substrates.

Care is taken not to exceed the stress levels that the mechanical connection between the two substrates is able to withstand. In one embodiment, a conductive epoxy is used to connect the two substrates 100, 102. The conductive epoxy exhibits a certain amount of elasticity that can absorb some of the stress. In another embodiment or in combination with the conductive epoxy bond, the perimeter ledge 106 has a sufficiently large surface area to withstand the stress without compromising the integrity of the mechanical connection. One of ordinary skill in the art may model the stresses between the two materials using a finite element analysis to analytically arrive at a minimum or optimum perimeter ledge surface area and test for sufficient elasticity of the conductive bonding material. In an embodiment of a package according to the present teachings, more than one first substrate 100 may be disposed in a single second substrate 102. The overall surface area of the first substrate 100 is smaller as compared to the equivalent purely ceramic package. The amount of thermal expansion is a function of the total surface area of the element for a given rise in temperature. Therefore, the smaller first substrates 100 having a smaller total surface area than the equivalent pure ceramic package decreases the total amplitude of thermal expansion, thereby also reducing the overall stress applied to the mechanical connection between the two substrates 100, 102 when compared to the equivalent stress between a pure ceramic package and the host PCB for the same IC 107.

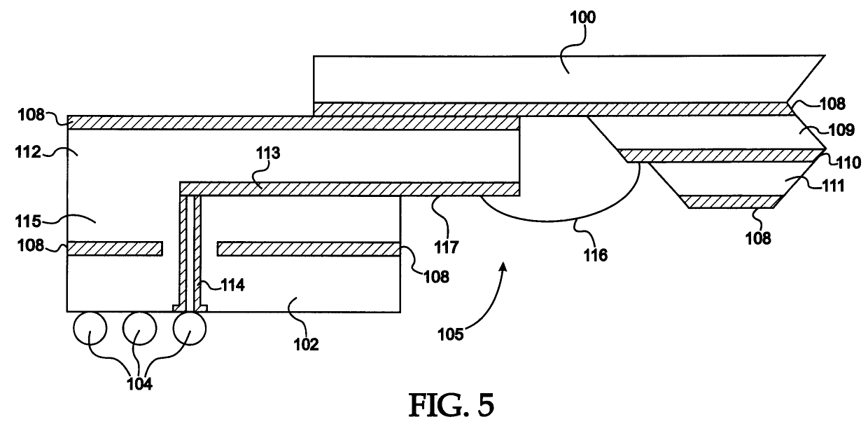

With specific reference to FIG. 5 of the drawings, there is shown a partial cross sectional view of a second embodiment of a package according to the present teachings in which the first substrate 100 is shown as a patterned and metalized multilayer substrate. The IC 107 is not shown in this view in order to focus on the details of an embodiment of interconnections between the first and second substrates 100, 102. In a specific embodiment, the first substrate 100 is ceramic and has a metalized ground plane 108, a first layer of dielectric 109, a metalized signal trace 110, a second layer of dielectric 111, and another metalized ground plane 108. The second substrate 102 also has a metalized ground plane 108, a first layer of dielectric 112, a signal trace layer 113 with a via 114 leading to one of the package interconnects 104, a second layer of dielectric 115, and another metalized ground plane 108 with a portion of the ground plane 108 having an unmetalized area to permit the via 114 to extend through the intermediate ground plane 108 and to the package interconnect 104. The second substrate 102 further includes a bond wire shelf 117 that permits electrical connection to an intermediate layer of the second substrate 102.

With further reference to FIG. 5 of the drawings, the signal traces 110, 113 of the first and second substrates 100, 102 are interconnected through bond wire 116. The ground plane 108 of the first substrate 100 rests on the ground plane 108 of the second substrate 102 and may be electrically and mechanically connected thereto using conventional means such as conductive epoxy. As one of ordinary skill in the art appreciates, the ground plane connection as shown provides for a unified package ground plane. The signal connection shown in FIG. 5 of the drawings comprising the signal trace 110, the bond wire 116, and the signal trace 113 is flanked by ground planes 108 providing for signal transmission and isolation at high signal frequencies similar to those found in coaxial structures. The via 114 electrically connects the signal trace 113 to the package interconnect 104 for delivery of the IC signal to the host PCB.

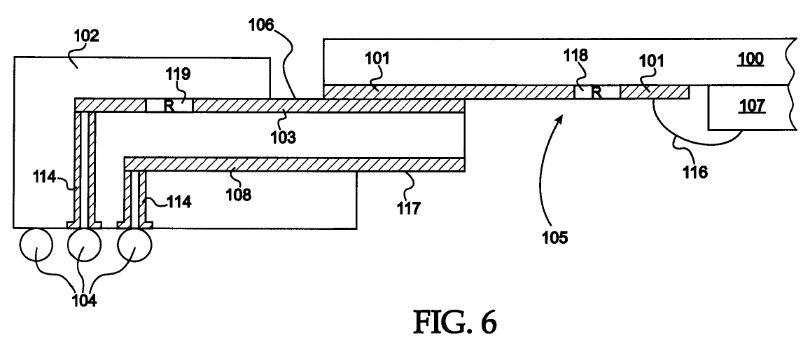

With specific reference to FIG. 6 of the drawings that illustrates a cross sectional view of another embodiment of a package according to the present teachings, wherein the perimeter ledge 106 of the second substrate 102 is recessed and the first substrate 100 is disposed in the recessed perimeter ledge 106. The IC 107 disposed on the first substrate 100 is wire bonded 116 to the signal trace 101. In the illustrated embodiment, the first substrate 100 has a resistor component 118 interposed within the signal trace 101. The illustration in FIG. 6 further shows a ground plane 108 in another layer of the second substrate 102 that has a wire bond shelf 117. A reference potential connection may be made between the IC 107 and the ground plane 108 by connection to the wire bond shelf although it is not shown in this particular cross sectional view. Also shown in FIG. 6 of the drawings is a passive component, specifically resistor 119, interposed in signal trace 103 on the second substrate 102. Both passive components 118, 119 are optional and may also be capacitive, inductive or a combination of impedances as dictated by the IC and system design.

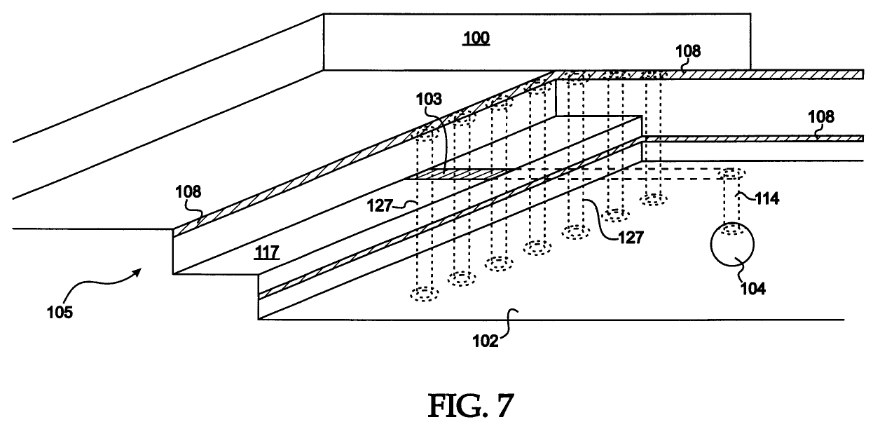

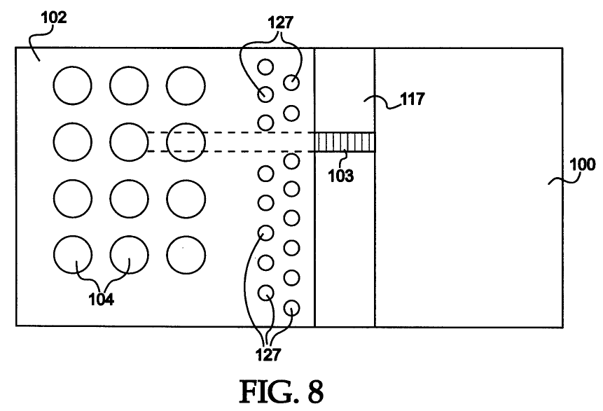

With specific reference to FIG. 7 of the drawings, there is shown a perspective view of another embodiment according to the present teachings that provides enhanced shielding for the IC 107 and components disposed on the first substrate 100. For purposes of clarity, only one side of a four sided reception cavity 105 is illustrated. In a specific embodiment, however, all sides of the reception cavity 105 are similarly configured. A plurality of ground vias 127 extend in a single or multiple row configuration around the perimeter of the reception cavity 105 and through the second substrate 102. Each ground via 127 in the plurality of ground vias 127 electrically connects to one or more ground planes 108 in one or more layers of the second substrate 102 including any ground plane 108 on an outside layer of the second substrate 102. One or more conductive elements 103 in the form of signal traces may electrically connect to respective ones of the interconnects 104 through a signal via 114 that connects the interconnect 104 to a conductive element 103 in the signal trace layer 113. One or more conductive elements 103 on the signal trace layer 113 extend between and past the ground vias 108 to present a landing at the wire bond shelf 117. To further clarify the embodiment of FIG. 7 and with specific reference to FIG. 8 of the drawings, there is shown a plan view of a portion of the package showing the interconnects 104 in relation to the ground vias 127 and one signal trace 103 on signal trace layer 113. The ground vias 127 may be a single or multiple column configuration and the conductive element 103 extends past the ground vias 127 without electrical connection thereto. The perimeter ground vias 127 provide an isolating electrical shield between reception cavities 105 and between the reception cavity 105 and the outside of the package.

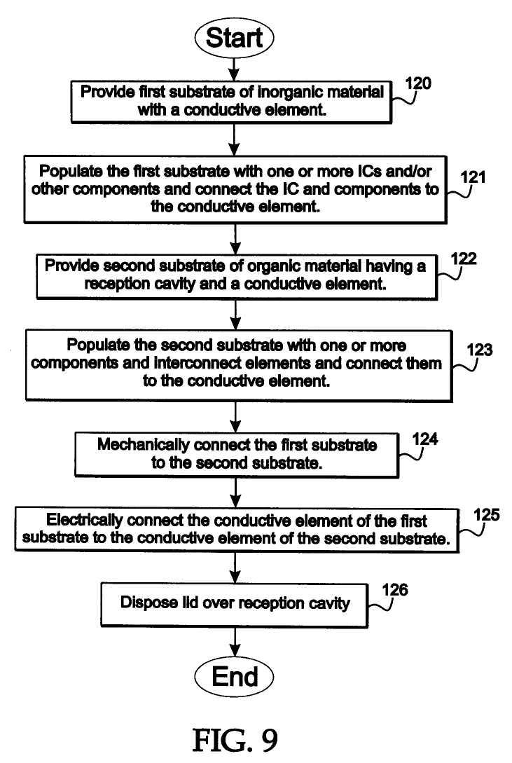

With specific reference to FIG. 9 of the drawings, a method according to the present teachings provides 120 a first substrate 100 made of an inorganic material and having a conductive element 101 or 108. The first substrate 100 is then populated 121 with the IC 107 and pads on the IC are connected to the conductive element 101 or 108 using conventional means. In one embodiment the conductive element is a signal trace 101 and in another embodiment, the conductive element is a ground plane 108. In yet another embodiment, the first substrate 100 has a plurality of signal traces 101, one or more connections to power and reference potential, and the ground plane 108. The first substrate may be either a single or multilayer structure. In yet another embodiment, other ICs and circuit components 118 may be disposed and interconnected on the first substrate 100 as appropriate for the specific application. The second substrate 102, made of an organic material and having a reception cavity 105 and a conductive element 103 or 108, is then provided 122. The reception cavity 105 of the second substrate 102 has perimeter dimensions that are smaller than perimeter dimensions of the first substrate 100. The second substrate 102 is populated 123 with interconnect elements 104 and optionally populated with circuit components 123. The first substrate 100 is mechanically connected 124 to the second substrate 102 such that the IC 107 is disposed within the reception cavity 105 of the second substrate 102. The conductive element 101 or 108 of the first substrate 100 is then electrically connected 125 to the conductive element 103 or 108 of the second substrate 102. The electrical connection may be made as part of the mechanical connection if there are a large number of connections or a connection over a large surface area such as a ground plane connection. Conventional electrical and mechanical connection means are appropriate such as solder and conductive epoxy. The lid or “glob top” is then disposed 126 over the reception cavity 105 to complete the IC assembly. As one of ordinary skill appreciates, the order of the steps to assemble the package may be altered. For example, the first and second substrates may first be assembled together and then populated with components and wire bonded. A preferred order of assembly depends upon the specific package, existing package assembly processes and ease of adaptation of the existing assembly processes to the present teachings.

Embodiments of the teachings are described herein by way of example with reference to the accompanying drawings describing a microelectronic package that provides the electrical signal transmission benefits of a ceramic package with the interconnect reliability and cost protection of a plastic package. Other variations, adaptations, and embodiments of the present teachings will occur to those of ordinary skill in the art given benefit of the present teachings.

1. An apparatus comprising:
A first substrate made of an inorganic material having at least one signal trace,
A second substrate made of an organic material having at least one signal trace, at least one interconnect and at least one reception cavity, wherein the first and second substrates are mechanically joined and the at least one signal trace of the first substrate is electrically connected to the at least one signal trace of the second substrate and the first substrate overlays the reception cavity.

2. An apparatus as recited in claim 1 wherein the first substrate is made of a material chosen from the group comprising glass and ceramic.

3. An apparatus as recited in claim 1 wherein the second substrate is made of a material chosen from the group comprising FR4, plastic, epoxy, glass plastic composite, and glass epoxy composite.

4. An apparatus as recited in claim 1 wherein components are disposed on the first substrate.

5. An apparatus as recited in claim 4 wherein the components are disposed on the first substrate within a perimeter of the reception cavity.

6. An apparatus as recited in claim 1 wherein components are disposed on the second substrate.

7. An apparatus as recited in claim 6 wherein the components are disposed on the second substrate on a side opposite the interconnect.

8. An apparatus as recited in claim 1 wherein the reception cavity is defined by a perimeter ledge and the at least one signal trace on the second substrate is on the perimeter ledge and the first substrate is disposed on the perimeter ledge wherein the signal trace of the second substrate contacts the signal trace of the first substrate.

9. An apparatus as recited in claim 8 wherein the perimeter ledge is recessed within the second substrate.

10. An apparatus as recited in claim 1 wherein the first substrate has a ground plane and the second substrate has a ground plane wherein the respective ground planes contact each other to become a continuous ground plane.

11. An apparatus as recited in claim 10 wherein the ground planes of the first and second substrates are electrically and mechanically connected to each other.

12. An apparatus as recited in claim 1 wherein the first substrate is a multilayer structure.

13. An apparatus as recited in claim 12 wherein the second substrate is a multilayer structure.

14. An apparatus as recited in claim 1 wherein the second substrate is a multilayer structure.

15. An apparatus as recited in claim 1 wherein a plurality of vias in the second substrate surround the reception cavity and are electrically connected to a reference potential.

16. A method of manufacturing a microelectronic package comprising:
Providing a first substrate made of an inorganic material, the first substrate having first perimeter dimensions and at least one conductive element,
Populating the first substrate with an IC,
Connecting a signal pad of the IC to the conductive element on the first substrate,
Providing a second substrate made of an organic material and having at least one reception cavity, the reception cavity having second perimeter dimensions smaller than the first perimeter dimensions and at least one conductive element connected to at least one interconnect,
Mechanically and electrically connecting the first substrate to the second substrate wherein the conductive element of the first substrate is connected to the conductive element of the second substrate and the IC is disposed within the reception cavity.

17. A method as recited in claim 16 and further comprising disposing a cover over the reception cavity.

18. A method as recited in claim 17 wherein the cover is a metal lid.

19. A method as recited in claim 17 wherein the cover is an encapsulant.

20. A method as recited in claim 16 wherein the conductive element is a signal trace.

21. A method as recited in claim 16 wherein the conductive element is a ground plane.

22. A method as recited in claim 16 wherein the first substrate is made of a material chosen from the group comprising glass and ceramic.

23. A method as recited in claim 16 wherein the second substrate is made of a material chosen from the group comprising FR4, plastic, epoxy, glass plastic composite, and glass epoxy composite.

24. A method as recited in claim 16 and further comprising populating the first substrate with additional electrical components.

25. A method as recited in claim 16 wherein the first substrate is connected to the second substrate wherein the IC is disposed within the perimeter dimensions of the reception cavity.

26. A method as recited in claim 16 further comprising the step of populating the second substrate with electrical components.

27. A method as recited in claim 26 wherein the components are disposed on the second substrate on a side opposite the interconnect.

28. A method as recited in claim 16 wherein the reception cavity is defined by a perimeter ledge and the conductive element on the second substrate is on the perimeter ledge and the first substrate is disposed on the perimeter ledge wherein the conductive element of the second substrate contacts the conductive element of the first substrate.

29. A method as recited in claim 28 wherein the perimeter ledge is recessed within the second substrate.

30. A method as recited in claim 16 wherein the first substrate is a multilayer structure.
